(19) United States
(12) Patent Application Publication
(10) Pub. No.: US 2012/0180862 A1
(43) Pub. Date: Jul. 19, 2012

(54) NON-CONTACTING BUS BARS FOR SOLAR CELLS AND METHODS OF MAKING NON-CONTACTING BUS BARS

(76) Inventor: Henry HIESLMAIR, Sunnyvale, CA (US)

(21) Appl. No.: 13/350,614

(22) Filed: Jan. 13, 2012

Related U.S. Application Data
(60) Provisional application No. 61/432,521, filed on Jan. 13, 2011.

(51) Int. Cl. H01L 31/0224; H01L 31/18

(52) U.S. Cl. 136/256; 438/98; 257/E31.124

(57) ABSTRACT

A photovoltaic module having non-contacting bus bars and methods of making non-contacting bus bars are disclosed. The fingers are screen printed on the substrate using a paste. The bus bar(s) can be formed over the fingers using a number of techniques that do not dissolve through the passivation layer of the substrate. The bus bar(s) can be screen printed over the fingers using a second paste that is more viscous and/or conductive than the first paste. The bus bar(s) can be a conductive trace that is deposited over the fingers. The bus bar(s) can be a metal wire coated with solder or paste that is positioned on the fingers. Metal plating techniques may also be used to thicken the fingers and/or bus bars. One or more doping steps may be used to form selective emitters under the fingers and bus bar.

### PRIORITY

The present application claims priority to U.S. Provisional Application No. 61/432,521, filed Jan. 13, 2011, and entitled “NON-CONTACTING BUS BARS,” the entirety of which is hereby incorporated by reference.

### BACKGROUND

1. Field

This invention relates to the art of methods for making solar cells and, more particularly, to non-contacting bus bars for solar cells and methods of making non-contacting bus bars.

2. Related Art

Solar cells, also known as photovoltaic (PV) cells, convert solar radiation into electrical energy. Solar cells are fabricated using semiconductor processing techniques, which typically, include, for example, deposition, doping and etching of various materials and layers. Typical solar cells are made on semiconductor wafers or substrates, which are doped to form p-n junctions in the wafers or substrates. Solar radiation (e.g., photons) directed at the surface of the substrate cause electron-hole pairs in the substrate to be broken, resulting in migration of electrons from the n-doped region to the p-doped region (i.e., an electrical current is generated). This creates a voltage differential between two opposing surfaces of the substrate. Metal contacts, coupled to electrical circuitry, collect the electrical energy generated in the substrate.

Silicon photovoltaic (PV) cells are manufactured using processes that are similar to conventional semiconductor processing techniques. However, the difference in value of a PV cell compared to a wafer is orders of magnitude. The PV industry needs high throughput at low capital and running cost. Also, the substrate for PV cells is typically very thin (e.g., <200 μm thick) and fragile.

Most silicon solar cells fabricated today use a screen print technique to screen print a silver paste on the front surface. This metal is then fired/dissolved through the front silicon nitride with a short thermal ramp to approximately 800 C. During this thermal cycle, the glass frit in the paste dissolves the silicon nitride and, upon cooling, the silver precipitates and forms crystallites that contact the silicon underneath. The standard pattern of this front contact are a series of parallel fine lines (fingers) of ˜100 μm width as well as two or three bus bars which are perpendicular to the fingers and are approximately 2 mm wide. Historically, is has been expedient to simultaneously screen print the fingers as well as the bus bars in a single pattern.

Since all of this metal is on the front side, shadowing is an issue. Thus there is an effort to reduce the width of these metal contacts. The finger widths are targeted to approach 60 to 70 μm. The bus bar widths are also becoming narrower. Unfortunately the conductivity also decreases as the width decreases. The industry is having problems screen printing such fine widths with any significant heights. To reliably push Ag pastes through fine features of a mask requires lower viscosity pastes, which unfortunately result in lower paste heights or aspect ratios.

### SUMMARY

The following summary of the invention is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

According to an aspect of the invention, a photovoltaic module is provided that includes a substrate; a passivation layer; a first layer over the passivation layer, the first layer consisting only of a plurality of fingers; and a bus bar over the first layer, wherein the bus bar does not contact the passivation layer.

The first layer may be formed by screen printing using a first paste and the bus bar is screen printed using a second paste. The first paste may have a high glass frit and the second paste may have a high conductivity.

The first layer may be formed by screen printing using a paste and the bus bar may be formed by metal plating.

The photovoltaic module may include a dopant ink between the silicon nitride passive layer and the first layer.

The substrate may be silicon and the passivation layer may be silicon nitride.

According to another aspect of the invention, a method of making a photovoltaic module is provided that includes screen printing fingers over a substrate using a first paste; and screen printing the bus bar over the fingers using a second paste, wherein the second paste is more viscous than the first paste.

The first paste may include grass frit, and the second paste does not include glass frit.

The method may further include firing the first paste before screen printing the bus bar. The method may further include co-firing the first paste and the second paste.

The method may further include screen printing a dopant ink and diffusing the dopant before screen printing the fingers.

The method may further include selectively doping a first region, the first region corresponding to the fingers; and selectively doping a second region, the second region corresponding to the bus bar. The first region may be selectively doped using a finger patterned shadow mask, and the second region may be selectively doped using a bus bar patterned shadow mask.

According to a further aspect of the invention, a method of making a photovoltaic module is provided that includes screen printing fingers over a substrate using a first paste; and forming the non-contacting bus bar over the fingers.

Forming the non-contacting bus bar over the fingers may include depositing a conductive trace over the bus bars. The conductive trace may be deposited using screen printing or an aerosol jet.

The method may further include thickening the fingers and the bus bar using metal plating. The metal plating may be light induced plating.

Forming the non-contacting bus bar over the fingers may include positioning a metal wire over the fingers. The metal wire may be coated with at least one of a paste and solder.

### BRIEF DESCRIPTION OF THE DRAWINGS

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale.

FIG. 1 illustrates a photovoltaic cell in accordance with one embodiment of the invention.

FIG. 2 is an end view of a photovoltaic cell with a bus bar in accordance with one embodiment of the invention.

FIG. 3 is a flow diagram showing a method of making the non-contacting bus bar in accordance with one embodiment of the invention.

FIGS. 3A-B are flow diagrams showing methods of making the non-contacting bus bar in accordance with embodiments of the invention.

FIGS. 4A-4B are flow diagrams showing methods of making the non-contacting bus bar in accordance with one embodiment of the invention.

FIG. 5 is a flow diagram showing a method of making the non-contacting bus bar in accordance with one embodiment of the invention.

FIG. 6 is a flow diagram showing a method of making the non-contacting bus bar in accordance with one embodiment of the invention.

### DETAILED DESCRIPTION

Embodiments of the invention are directed to non-contacting bus bars. Two changes can be made to improve conductivity of a photovoltaic cell. First, the height of the fingers and bus bars can be increased. The aspect ratio of a screen printed paste depends upon its viscosity and the screen/stencil thickness. By using a paste with a higher viscosity for the bus bars, a thicker bus bar can be formed. Second, the conductivity of the paste itself is reduced by the glass frit in the paste. The glass frit is necessary to dissolve the front silicon nitride passivation layer, allowing the silver to make contact with the doped substrate. In embodiments of the invention, the first screen print is performed with a high glass frit paste to form the fingers, and then a second paste that is a non-glass frit paste and is highly conductive can be used to form the bus bars. The aspect ratio of this first paste can be increased with an aligned second screen print paste. Alternatively, the first high glass frit screen print can be fired and followed by a metal plating step.

Embodiments of the invention are advantageous because it reduces the metal-silicon recombination rate and improves conductivity of the bus bar. With these new two-step approaches, the bus bars need not be formed in the traditional manner. A finger only pattern for the first layer can be followed by many other processes to form the bus bars. In the double print case, the first paste with high glass frit can be in a finger only pattern while the second highly conductive paste, includes the finger as well as the bus bars or only the bus bars. In one particular embodiment, the first paste is HERAEUS SOL952, and the second paste is HERAEUS CL80-9381M. When fired, the bus bar regions do not dissolve through the silicon nitride passivation layer. This has a beneficial effect of lowering the total recombination.

In silicon solar cells, metal contacted regions are necessary, but have a deleterious recombination effect. A metal contacted surface can have recombination of 1000s of fA/cm² depending upon the doping underneath the contacted regions. The emitter recombination, called Joe, is the weighted sum of all of the recombination in the front emitter. For a 156 mm solar cell with 69 fingers of 100 μm width and two bus bars of 2 mm width, the fraction of area contacted is 4.4% for the fingers only and 7% for fingers and bus bars. For good emitters with good passivation, the Joe can be 50 to 300 fA/cm² in non-metalized regions. However, metal contacted regions can have Joe of 3000 fA/cm² or more. The net emitter Joe of a typical cell is thus:

$$Joe = 93 \% * 150 + 7 \% * 3000 = 350 \frac{fA}{{cm}^{2}}$$

With bus bars that do not contact the silicon below, the Joe improves:

$$Joe = 95.6 \% * 150 + 4.4 \% * 3000 = 275 \frac{fA}{{cm}^{2}}$$

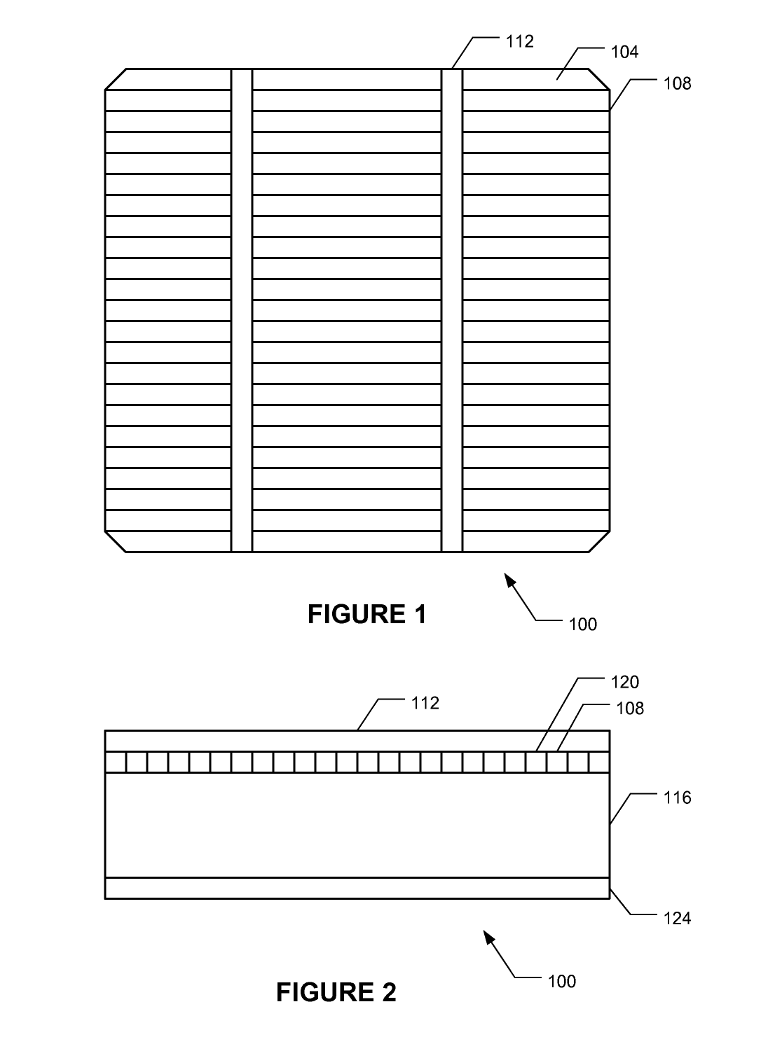

FIG. 1 illustrates a photovoltaic cell 100 according to some embodiments of the invention. The photovoltaic cell 100 includes a base 104, multiple fingers 108 and two bus bars 112. It will be appreciated that the photovoltaic cell may include fewer or more fingers 108 than shown in FIG. 1, and that the photovoltaic cell may include fewer than two or more than two bus bars 112.

FIG. 2 is an end view of the photovoltaic cell 100 according to some embodiments of the invention. The base 104 includes a substrate 116 and a passivation layer 120 formed over the substrate 116. The fingers 108 are formed in the passivation layer 120. The bus bar 112 is formed over the fingers 108 and the passivation layer 120. A contact 124 is formed on the side of the substrate opposite the fingers 108 and bus bar 112. Selective emitters (not shown) are formed in the substrate 104.

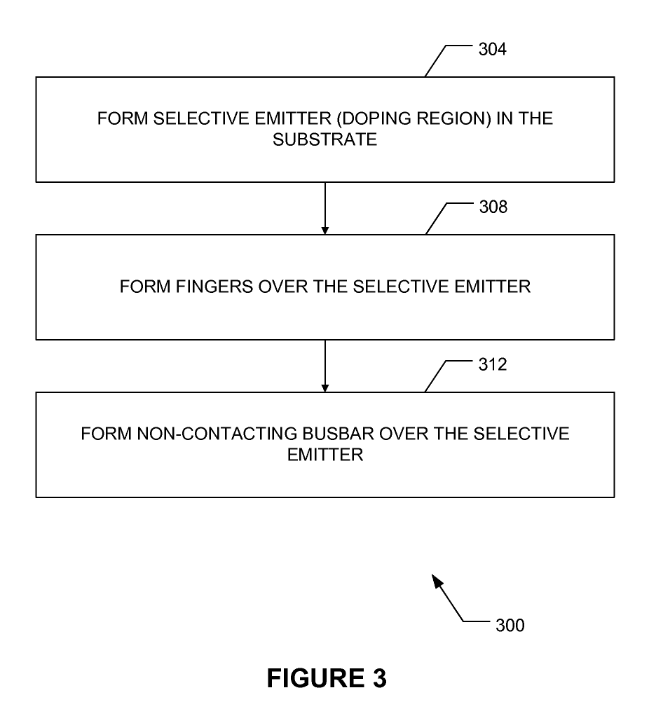

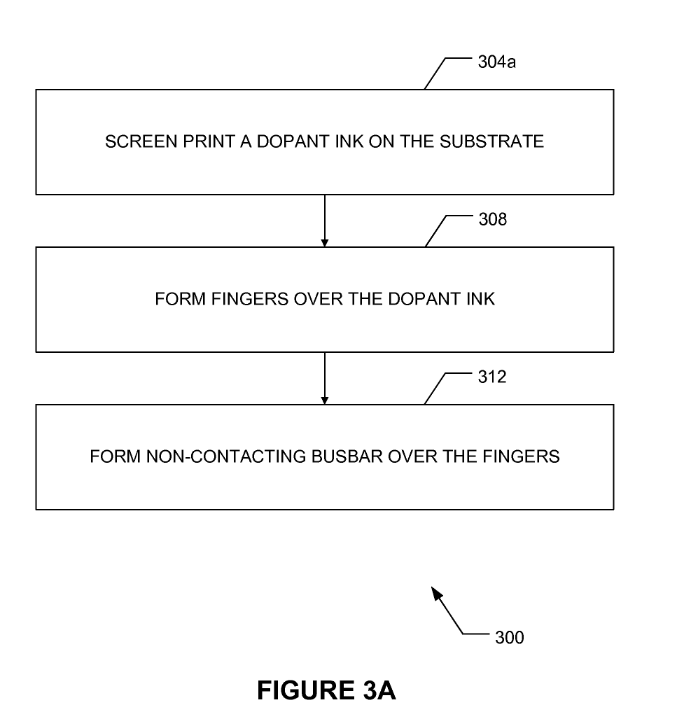

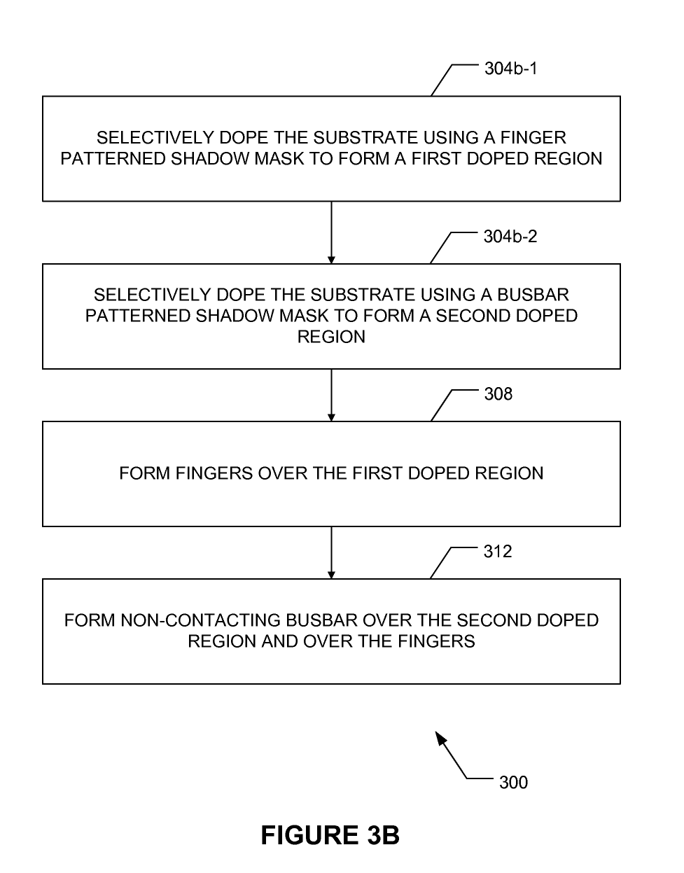

FIG. 3 illustrates a method of making the photovoltaic cell of FIGS. 1 and 2 according to some embodiments of the invention. As shown in FIG. 3, the method 300 includes forming a selective emitter (doping region) in the substrate (block 304), forming fingers over the selective emitter (block 308) and forming non-contacting bus bars over the selective emitter (block 312).

The higher the doping under a metal contacted region, the lower the recombination at the metal-silicon interface. The focus on selective emitters—higher doping under metal lines and lower doping between metal—is primarily motivated by contact resistance to the silver paste. An additional benefit is a reduction of the metal-silicon recombination rate or Joe.

FIGS. 3A and 3B illustrate detailed methods of forming the selective emitter in accordance with certain embodiments of the invention. As shown in FIG. 3A, the selective emitter may be formed by screen printing a dopant ink on the substrate (block 304a). The method may also include forming a phosphorus diffusion to create the highly doped pattern of the fingers and the bus bar.

It will be appreciated that other methods, such as laser over-doping and ion-implantation, may be used. The methods have a throughput decrease because they also require forming a doping region under the bus bars. In the case of laser over-doping, the laser spot can be the a finger width wide, but the bus bar width would require multiple passes or a different laser optics.

For ion-implantation and more generally, for methods that utilize a shadow mask, two deposition steps are required, as shown in FIG. 3B. As shown in FIG. 3B, the selective emitter is formed by selectively doping the substrate using a finger patterned shadow mask (block 304b-1), and selectively doping the substrate using a bus bar patterned shadow mask (bock 304b-2). It will be appreciated that other doping methods may be used to form the separate doping regions as described above with reference to FIG. 3B, including laser selective doping, implantation selective doping, and PVD selective doping, and the like.

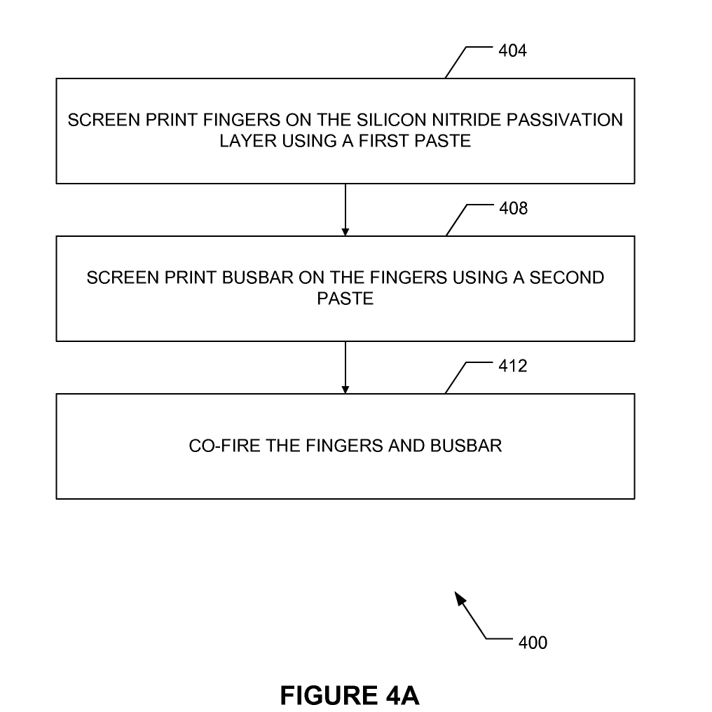

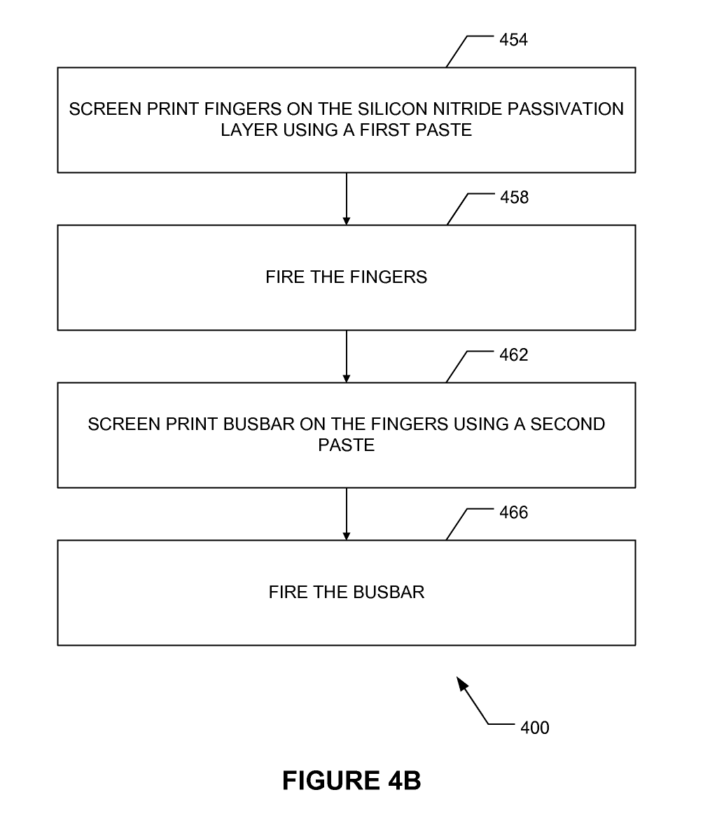

FIGS. 4A-B illustrate exemplary methods for forming a photovoltaic module having a non-contacting bus bar according to some embodiments of the invention. In FIGS. 4A-4B the non-contacting bus bar is formed using a second screen printing process. In particular, after the finger screen print and paste dry steps, a second screen print step can print the bus bars. The paste for the bus bars can be highly viscous, and printed with a thicker screen to achieve a higher aspect ratio than the fingers. The bus bar paste can also be free of glass frit which enhances conductivity and will not dissolve through the silicon nitride passivation. In one particular embodiment, the finger paste is HERAEUS SOL952, and the bus bar paste is HERAEUS CL80-9381M.

In one embodiment, the fingers and bus bars are co-fired, as shown in FIG. 4A. In another embodiment, the fingers are fired first and then the bus bars are screen printed with a lower temperature paste that consolidates during a forming gas anneal or other lower temperature anneal, as shown in FIG. 4B.

In particular, as shown in FIG. 4A, the method 400 begins by screen printing fingers on the silicon nitride passivation layer using a first paste (block 404). The method 400 continues by screen printing the bus bar on the fingers using a second paste (block 408) and co-firing the fingers and bus bar (block 412). As shown in FIG. 4B, the method 400 begins by screen printing the fingers on the silicon nitride passivation layer using a first paste (block 404) and firing the fingers (block 458). The method 400 continues by screen printing the bus bar on the fingers using a second paste (block 462) and firing the bus bar (block 466). As described above, in one particular embodiment, the first paste is HERAEUS SOL952, and the second paste is HERAEUS CL80-9381M.

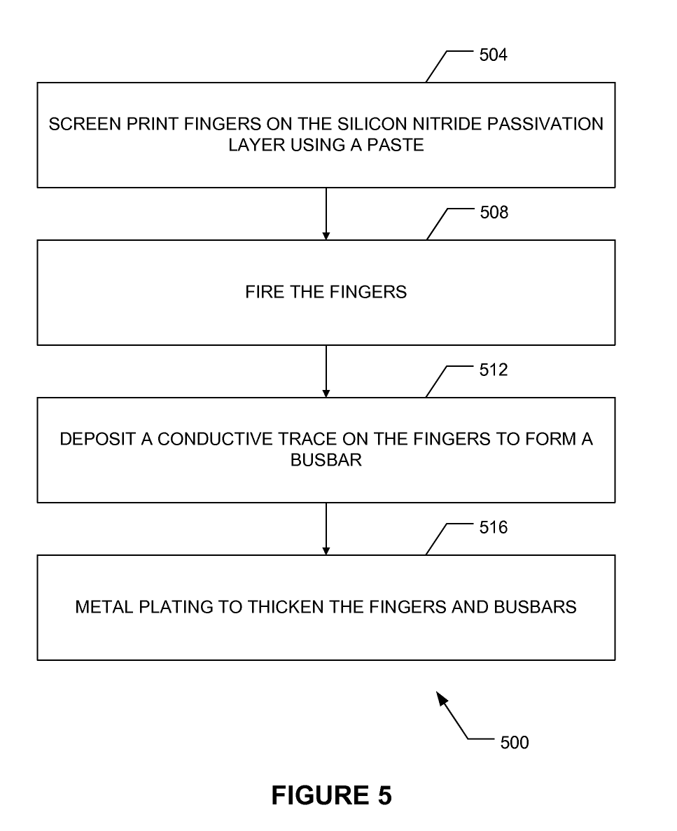

FIG. 5 illustrates a method of making the photovoltaic module, in which the non-contacting bus bar is formed by a seed and plated bus bar that is deposited over the fingers. In particular, after the screen printing and firing of the fingers, a conductive trace can be deposited for the bus bars. The conductive trace can be deposited using, for example, screen printing, aerosol jet, and the like. In some embodiments, the fingers and/or the bus bar(s) are then thickened. In some embodiments, the fingers and/or the bus bars are thickened using metal plating techniques, such as, for example, light induced plating (LID) and the like.

In particular, as shown in FIG. 5, the method 500 begins by screen printing fingers on the silicon nitride passivation layer using a paste (block 504) and firing the fingers (block 508). The method 500 continues by depositing a conductive trace on the fingers to form a bus bar (block 512). The method optionally continues by metal plating to thicken the fingers and bus bar(s) (block 516).

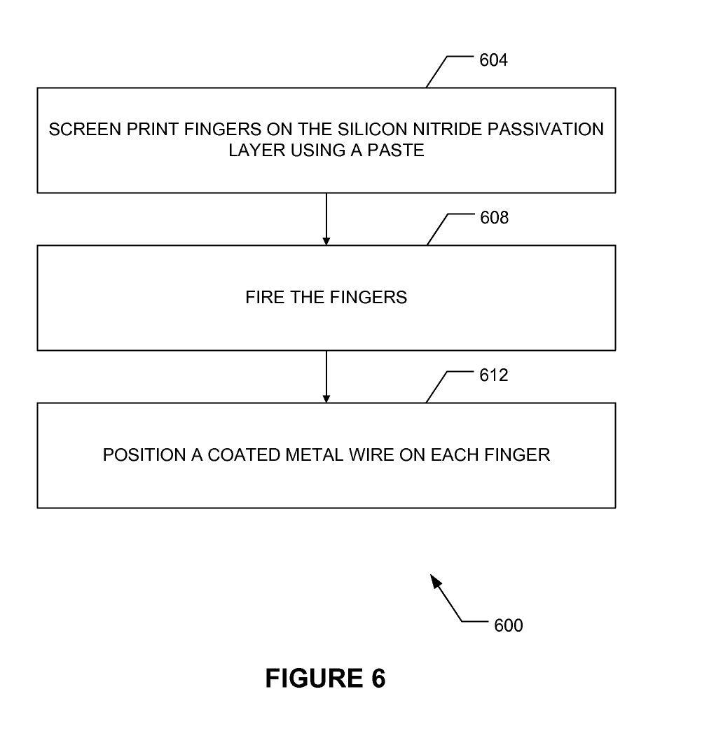

FIG. 6 illustrates a method of making the photovoltaic module in which a solid bus bar can be used to form the non-contacting bus bar. After the fingers are screen printed, a round or rectangular cross sectioned metal wire can be placed on the surface to contact each finger. The metal wire can be placed during firing or after firing. It will be appreciated that because it is important that the bus bar contact each finger, in some embodiments, the bus bar may be pre-coated with a paste or solder. The wire can be coated before or after firing the fingers through the passivation layer.

In particular, as shown in FIG. 6, the method 600 begins by screen printing fingers on the silicon nitride passivation layer using a paste (block 604) and firing the fingers (block 608). The method 600 continues by positioning a coated metal wire on each finger (block 612).

It should be understood that processes and techniques described herein are not inherently related to any particular apparatus and may be implemented by any suitable combination of components. Further, various types of general purpose devices may be used in accordance with the teachings described herein. The present invention has been described in relation to particular examples, which are intended in all respects to be illustrative rather than restrictive. Those skilled in the art will appreciate that many different combinations will be suitable for practicing the present invention.

Moreover, other implementations of the invention will be apparent to those skilled in the art from consideration of the specification and practice of the invention disclosed herein. Various aspects and/or components of the described embodiments may be used singly or in any combination. It is intended that the specification and examples be considered as exemplary only, with a true scope and spirit of the invention being indicated by the following claims.

What is claimed is:

1. A photovoltaic module comprising:
a substrate;
a passivation layer;
a first layer over the passivation layer, the first layer consisting only of a plurality of fingers; and
a bus bar over the first layer, wherein the bus bar does not contact the passivation layer.

2. The photovoltaic module of claim 1, wherein the first layer is formed by screen printing using a first paste and the bus bar is screen printed using a second paste.

3. The photovoltaic module of claim 2, wherein the first paste has a high glass frit and the second paste has a high conductivity.

4. The photovoltaic module of claim 1, wherein the first layer is formed by screen printing using a paste and the bus bar is formed by metal plating.

5. The photovoltaic module of claim 1, further comprising a dopant ink between the silicon nitride passive layer and the first layer.

6. The photovoltaic module of claim 1, wherein the substrate comprises silicon and wherein the passivation layer comprises silicon nitride.

7. A method of making a photovoltaic module comprising:
screen printing fingers over a substrate using a first paste; and
screen printing the bus bar over the fingers using a second paste, wherein the second paste is more viscous than the first paste.

8. The method of claim 7, wherein the first paste comprises grass frit, and wherein the second paste does not comprise glass frit.

9. The method of claim 7, further comprising firing the first paste before screen printing the bus bar.

10. The method of claim 7, further comprising co-firing the first paste and the second paste.

11. The method of claim 7, further comprising screen printing a dopant ink and diffusing the dopant before screen printing the fingers.

12. The method of claim 7, further comprising:
selectively doping a first region, the first region corresponding to the fingers; and
selectively doping a second region, the second region corresponding to the bus bar.

13. The method of claim 12, wherein the first region is selectively doped using a finger patterned shadow mask, and wherein the second region is selectively doped using a bus bar patterned shadow mask.

14. A method of making a photovoltaic module comprising:
screen printing fingers over a substrate using a first paste; and
forming the non-contacting bus bar over the fingers.

15. The method of claim 14, wherein forming the non-contacting bus bar over the fingers comprises:
depositing a conductive trace over the bus bars.

16. The method of claim 15, wherein the conductive trace is deposited using one selected from the group consisting of screen printing and an aerosol jet.

17. The method of claim 14, further comprising thickening the fingers and the bus bar using metal plating.

18. The method of claim 17, wherein the metal plating comprises light induced plating.

19. The method of claim 14, wherein forming the non-contacting bus bar over the fingers comprises:
positioning a metal wire over the fingers.

20. The method of claim 19, wherein the metal wire is coated with at least one of a paste and solder.
